(19) United States
(12) Patent Application Publication
(10) Pub. No.: US 2007/0281486 A1
(43) Pub. Date: Dec. 6, 2007

(54) Slurry composition, method of polishing an object layer and method of manufacturing a non-volatile memory device using the slurry composition

(75) Inventors: Eui-Jin Han, Yongin-si (KR); Nam-Soo Kim, Suwon-si (KR); Bong-Su Ahn, Seoul (KR); Dong-Jun Lee, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/809,672

(22) Filed: Jun. 1, 2007

(30) Foreign Application Priority Data
Jun. 2, 2006 (KR) 10-2006-0049882

(51) Int. Cl. H01L 21/461; H01L 21/302

(52) U.S. Cl. 438/692; 451/41; 438/693; 438/694

(57) ABSTRACT

Methods of polishing an object layer and for manufacturing a non-volatile memory device that incorporates such a polished object layer using a specially formulated slurry composition are disclosed. The slurry compositions include a ceria abrasive, a nonionic surfactant having a hydrophilic-lipophilic balance (HLB) value in a range of about 12 to about 17, and water. The nonionic surfactant is selected such that it may be adsorbed onto a hydrophobic layer to protect the hydrophobic layer from the ceria abrasive during a polishing operation. The slurry compositions may have a relatively high polishing rate for a hydrophilic layer and at the same time a relatively low polishing rate for a hydrophobic layer. Thus, the slurry compositions may be applied during a process for polishing the hydrophilic layer using the hydrophobic layer as a polishing stop layer.

### CROSS-REFERENCE TO RELATED APPLICATIONS

This application claims priority under 35 U.S.C. § 119 to Korean Patent Application No. 2006-49882, filed on Jun. 2, 2006, the contents of which are herein incorporated by reference in their entireties.

### BACKGROUND OF THE INVENTION

1. Field of the Invention

Example embodiments of the present invention relate to slurry compositions for semiconductor fabrication, methods of polishing an object layer using the slurry compositions, and methods of manufacturing a non-volatile memory device using the slurry compositions. More particularly, example embodiments of the present invention relate to slurry compositions having a relatively high polishing selectivity with respect to a hydrophilic layer and a relatively low polishing selectivity with respect to a hydrophobic layer, methods of polishing an object layer using the slurry compositions, and a method of manufacturing a non-volatile memory device using the slurry compositions.

2. Description of the Related Art

In a method for manufacturing a semiconductor device, structures of the semiconductor device are generally formed by performing several sequential fabrication processes, such as a deposition process, a patterning process, an etching process, a polishing process and the like.

In many cases for manufacturing a semiconductor device, it is required to form a structure having a substantially flat surface. For example, a chemical mechanical polishing (CMP) process is frequently used for forming a semiconductor structure having a substantially flat surface.

In the CMP process, a semiconductor substrate to be polished is located on a wafer carrier, and then a slurry composition including an abrasive is provided to a polishing pad. While the semiconductor substrate is in contact with the polishing pad, the semiconductor substrate and the polishing pad are rotated together and pressurized. As a result, the semiconductor substrate is planarized. Particularly, the semiconductor substrate is mechanically polished by rubbing the abrasive of the slurry composition and a rugged surface of the polishing pad against the semiconductor substrate. Simultaneously, the semiconductor substrate is chemically polished by reacting chemical components of the slurry composition with surface substances of the semiconductor substrate.

A polishing efficiency for such a CMP process may be determined based on a particular combination of a CMP apparatus, a chemical composition of the slurry, a type of the polishing pad, etc. The proper selection/formation of the chemical composition of the slurry may greatly contribute to improving the polishing efficiency.

A single slurry composition exhibits different polishing rates relative to various substrate layers in accordance with the properties or types of the several layers. Thus, one type of a layer may be selectively polished relative to the other types of layers. For example, one layer of the group consisting of an oxide layer, a nitride layer, a polysilicon layer and a metal layer, which are widely used in manufacturing a semiconductor device, can be selectively polished by the CMP process due to the differences in the polishing rates of such layers.

Slurry compositions, which have a relatively high polishing rate for a polysilicon layer and also a relatively low polishing rate for an oxide layer are widely used. However, as demand increases for semiconductor devices having a high integration degree, a slurry composition having an inverse or opposite type of polishing selectivity has been found to be required. For example, in manufacturing a non-volatile memory device such as a flash memory device, one step in the fabrication process requires using a slurry composition having a relatively high polishing rate for a hydrophilic oxide layer and at the same time a relatively low polishing rate for a hydrophobic polysilicon layer. Such a slurry composition having a relatively high polishing selectivity for a hydrophilic layer and a relatively low polishing selectivity for a hydrophobic layer is not currently known in this art. Thus, there is an unmet need for a slurry composition having this desired polishing selectivity.

These and other deficiencies in and limitations of the prior art are met in whole, or at least in part, by the slurry compositions and the methods of this invention.

### SUMMARY OF THE INVENTION

Example embodiments of the present invention provide slurry compositions having a high polishing selectivity of a hydrophilic layer relative to that of a hydrophobic layer.

Example embodiments of the present invention also provide methods of polishing an object layer using the above-mentioned slurry compositions.

Example embodiments of the present invention also provide methods of manufacturing a non-volatile memory device using the above-mentioned slurry compositions.

According to one aspect of the present invention, a slurry composition in accordance with this invention includes a ceria abrasive, a nonionic surfactant having a hydrophilic-lipophilic balance (HLB) value in a range of about 12 to about 17, and water. The nonionic surfactant is adsorbed onto a hydrophobic layer to protect the hydrophobic layer from the ceria abrasive.

In another example embodiment of the present invention, the nonionic surfactant may include polyoxyethylene lauryl ether, polyoxyethylene cetyl ether, polyoxyethylene oleyl ether, polyoxyethylene sorbitan monolaurate, polyoxyethylene isooctylphenyl ether or combinations thereof.

In another example embodiment of the present invention, the slurry composition may consist essentially of about 0.001 to about 5 percent by weight of the ceria abrasive, about 0.001 to about 0.1 percent by weight of the nonionic surfactant, and the remainder being water.

In another example embodiment of the present invention, the slurry composition may further include a dispersing agent for dispersing the ceria abrasive. Examples of the dispersing agent may include polyacrylic acid and derivatives thereof.

In another example embodiment of the present invention, the slurry composition may consist essentially of about 0.001 to about 5 percent by weight of the ceria abrasive, about 0.5 to about 3.5 percent by weight of the dispersing agent, about 0.001 to about 0.1 percent by weight of the nonionic surfactant, and the remainder being water.

In another example embodiment of the present invention, the ceria abrasive may have an average particle size in a range of about 50 to about 400 nm, and preferably in a range of about 100 to about 200 nm.

In another example embodiment of the present invention, the slurry composition may have a pH of about 5 to about 8.

According to another aspect of the present invention, there is provided a method of polishing an object layer, such as a substrate layer of a semiconductor device. In the method of polishing the object layer, a polishing stop layer is formed on a substrate, and then the object layer is formed on the polishing stop layer. The object layer is polished by bringing the exposed surface of the object layer into contact with a polishing pad while a slurry composition is provided to the polishing pad until the polishing stop layer is exposed. In accordance with this invention, the slurry composition includes a ceria abrasive, a nonionic surfactant having a hydrophilic-lipophilic balance (HLB) value in a range of about 12 to about 17, and water.

In an example embodiment of the present invention, the polishing stop layer may have the property of hydrophobicity and the object layer may have the property of hydrophilicity. For example, the polishing stop layer may include or consist essentially of polysilicon, and the object layer may include or consist essentially of silicon oxide.

In another example embodiment of the present invention, a polishing selectivity between the object layer and the polishing stop layer may be in a range of about 30:1 to about 150:1.

In another example embodiment of the present invention, the nonionic surfactant may be selected from the group consisting of polyoxyethylene lauryl ether, polyoxyethylene cetyl ether, polyoxyethylene oleyl ether, polyoxyethylene sorbitan monolaurate, polyoxyethylene isooctylphenyl ether, and mixtures thereof.

In another example embodiment of the present invention, the slurry composition may include or consist essentially of about 0.001 to about 5 percent by weight of the ceria abrasive, about 0.001 to about 0.1 percent by weight of the nonionic surfactant, and the remainder being water.

In another example embodiment of the present invention, the slurry composition may further include a dispersing agent for dispersing the ceria abrasive.

According to still another aspect of the present invention, there is provided a method of manufacturing a non-volatile memory device. In the method of manufacturing the non-volatile memory device, isolation layers are formed to have upper portions protruding from a substrate. A tunnel oxide layer is formed on the substrate between the isolation layers, and then a conductive layer is formed on the tunnel oxide layer and on sidewalls and upper faces of the isolation layers. A sacrificial layer is formed on the substrate to cover the conductive layer, and then the sacrificial layer is polished by a polishing process using a slurry composition in accordance with this invention until the conductive layer is exposed. In one embodiment of this method, the slurry composition used during the polishing process includes a ceria abrasive, a nonionic surfactant having a hydrophilic-lipophilic balance (HLB) value in a range of about 12 to about 17 and water. The conductive layer exposed by such polishing process is then partially removed until the upper faces of the isolation layers are exposed to thereby form a floating gate electrode on the substrate. The sacrificial layer and the upper portions of the isolation layers protruding from the substrate are then removed from the substrate so as to expose the floating gate electrode. Next, a dielectric layer is formed on the floating gate electrode, and then a control gate electrode is formed on the dielectric layer.

In another example embodiment of the present invention, the conductive layer in the above-described method may be formed using polysilicon and the sacrificial layer may be formed using silicon oxide.

In another example embodiment of the present invention, a polishing selectivity of the sacrificial layer relative to the conductive layer may be in a range of about 30:1 to about 150:1 while performing the polishing process.

In another example embodiment of the present invention, the nonionic surfactant may be selected from the group consisting of polyoxyethylene lauryl ether, polyoxyethylene cetyl ether, polyoxyethylene oleyl ether, polyoxyethylene sorbitan monolaurate, polyoxyethylene isooctylphenyl ether, and mixtures thereof.

In another example embodiment of the present invention, a partial removal of the exposed conductive layer may be continuously carried out by the polishing process.

In another example embodiment of the present invention, the conductive layer may be removed at a polishing rate of about 10 to about 60 Å/min.

In another example embodiment of the present invention, the conductive layer may be formed to have a thickness substantially thinner than half of the width (distance) between the isolation layers.

According to the present invention, the slurry composition preferably demonstrates a relatively high polishing rate for a hydrophilic layer, such as a silicon oxide layer, and also a relatively low polishing rate for a hydrophobic layer, such as a polysilicon layer. Therefore, the slurry composition may be applied during a polishing process in which the hydrophobic layer is used as a polishing stop layer and the hydrophilic layer is used as a polishing object layer. Additionally, after the hydrophilic layer is polished using the hydrophobic layer as the polishing stop layer, the hydrophobic layer may itself be polished using the same slurry composition so as to have a substantially uniform thickness and a substantially even surface. Furthermore, a slurry composition formulated and used in accordance with this invention may effectively prevent the surface of the hydrophobic layer from being damaged by the abrasive included in the slurry composition.

### BRIEF DESCRIPTION OF THE DRAWINGS

The above and other features and advantages of the present invention will become more apparent by being described in detailed example embodiments thereof with reference to the accompanying drawings, in which:

FIG. 1 is a graph showing polishing rates and polishing selectivities for a polysilicon layer and a silicon oxide layer on which CMP processes were performed using slurry compositions prepared in accordance with Examples 1 to 5 hereinafter;

FIG. 2 is a graph showing polishing rates and polishing selectivities for a polysilicon layer and a silicon oxide layer on which CMP processes were performed using slurry compositions prepared in accordance with Examples 6 to 8 and the Comparative Example hereinafter;

FIG. 3 is a graph showing the number of damaged polysilicon layers on which CMP processes were performed using slurry compositions prepared in accordance with Examples 6 to 8 and the Comparative Example hereinafter;

FIGS. 4A to 4B are schematic perspective views illustrating a method of polishing an object layer in accordance with an example embodiment of the present invention; and

FIGS. 5A to 5I are schematic perspective views illustrating a method of manufacturing a non-volatile memory device in accordance with an example embodiment of the present invention.

### DETAILED DESCRIPTION OF THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or alternatively intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will also be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another. Thus, a first element, component, region, layer or section discussed below could in an alternative description be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Slurry Composition

A slurry composition according to the present invention demonstrates a relatively high polishing selectivity between a hydrophilic layer and a hydrophobic layer, and thus the slurry composition may be applied to preferentially polish a hydrophilic layer relative to a hydrophobic layer while performing a chemical mechanical polishing (CMP) process. When the hydrophilic layer is an object layer and the hydrophobic layer is a polishing stop layer, the slurry composition may be used for selectively polishing the hydrophilic layer. For example, the hydrophilic layer may be a silicon oxide layer and the hydrophobic layer may be a polysilicon layer.

The slurry composition of the present invention may have a high polishing rate for the hydrophilic layer, and also a very low polishing rate for the hydrophobic layer. As a result, the slurry composition may have a high polishing selectivity of the hydrophilic layer relative to the hydrophobic layer. For example, the slurry composition used in the CMP process may have a relatively high polishing rate for the hydrophilic layer in a range of about 1,500 to about 4,000 Å/min, and preferably in a range of about 2,000 to about 4,000 Å/min. At the same time, the slurry composition may also have a relatively low polishing rate for the hydrophobic layer in a range of about 10 to about 60 Å/min, and preferably about 10 to about 30 Å/min. Therefore, the slurry composition may have a polishing selectivity between the hydrophilic layer and the hydrophobic layer of at least about 30:1, and preferably a polishing selectivity of at least about 100:1.

When a polishing process is performed on a structure that includes a hydrophobic layer with a hydrophilic layer formed on the hydrophobic layer, the slurry composition may effectively polish the hydrophilic layer using the hydrophobic layer as a polishing stop layer. In addition, after polishing the hydrophilic layer until the hydrophobic layer is exposed, the exposed hydrophobic layer may be etched using the same slurry composition so as to have a substantially uniform thickness and an even surface.

One embodiment of a slurry composition of the present invention includes a ceria abrasive, a nonionic surfactant having a hydrophilic-lipophilic balance (HLB) value in a range of about 12 to about 17, and water.

The slurry compositions of the present invention include a ceria (CeO₂) abrasive. It has been found that the ceria abrasive may exhibit a high polishing rate for the hydrophilic layer and at the same time a low polishing rate for the hydrophobic layer. Thus, the ceria abrasive may be used for polishing the hydrophilic layer using the hydrophobic layer as a polishing stop layer. By contrast, a silica abrasive, such as fumed silica or colloidal silica, may have a polishing rate of the hydrophobic layer that is substantially greater than that of the ceria abrasive. Therefore, such a silica abrasive may excessively etch the hydrophobic layer, and thus the hydrophobic layer may not properly function as a polishing stop layer.

A particle size or distribution of particle sizes and the relative proportion of the ceria abrasive included in the slurry composition of the present invention may influence a polishing efficiency of the polishing process. When the particle size of the ceria abrasive is too great, a stress applied to the hydrophobic layer may increase during the polishing process, and thus grains comprising a surface of the hydrophobic layer may be partially separated from the hydrophobic layer, which is not desirable because of the damage to that layer. As the particle size of the ceria abrasive is decreased, damages of the above type to the hydrophobic layer may accordingly be reduced. However, when the particle size of the ceria abrasive is too small, a surface roughness of the hydrophobic layer may be caused by the in-situ polishing process and, as a result, the surface may be deteriorated. Therefore, the ceria abrasive may preferably have a particle size of about 50 to about 400 nm, and more preferably a particle size of about 100 to about 200 nm.

The amount (proportion) of the ceria abrasive in the slurry composition may affect a polishing rate of the hydrophilic layer and a polishing selectivity between the hydrophilic layer and the hydrophobic layer. In accordance with an example embodiment of the present invention, the slurry composition may include the ceria abrasive in a range of about 0.001 to about 5 percent by weight, and preferably in a range of about 0.1 to about 3.5 percent by weight, based on a total weight of the slurry composition.

The slurry composition of the present invention may also advantageously include a nonionic surfactant having a hydrophilic-lipophilic balance (HLB) value in a range of about 12 to about 17. The HLB value indicates a relative degree between hydrophilicity and lipophilicity for a surfactant. A relatively smaller HLB value means that the surfactant is more lipophilic, and a relatively larger HLB value denotes that the surfactant is more hydrophilic. The HLB value is therefore an index of the surfactant with respect to hydrophilicity and lipophilicity.

Examples of the nonionic surfactant that may be used in the slurry compositions of this invention include polyoxyethylene lauryl ether, polyoxyethylene cetyl ether, polyoxyethylene oleyl ether, polyoxyethylene sorbitan monolaurate, polyoxyethylene isooctylphenyl ether, and mixtures thereof. The HLB values of the nonionic surfactants listed above are shown in Table 1 below.

TABLE 1

| Type of Nonionic Surfactant | HLB Value |
|---|---|
| Polyoxyethylene Lauryl Ether | 16.9 |
| Polyoxyethylene Cetyl Ether | 15.7 |
| Polyoxyethylene Oleyl Ether | 12.4 |
| Polyoxyethylene Sorbitan Monolaurate | 16.7 |
| Polyoxyethylene Isooctylphenyl Ether | 13.5 |

The nonionic surfactant may help in protecting the hydrophobic layer from being damaged during the polishing process performed using the slurry composition. When a slurry composition including the ceria abrasive but not the nonionic surfactant is used during the polishing process, the hydrophilic layer may still be effectively polished but the polishing rate of the hydrophobic layer in this case may also be greater than desired. Thus, the slurry composition without the nonionic surfactant may not be suitable for performing the polishing process in situations where the hydrophilic layer is to be polished using the hydrophobic layer as a polishing stop layer.

A hydrophobic portion of the nonionic surfactant that has an HLB value of about 12 to about 17 may become oriented so as to face the hydrophobic layer of a semiconductor device while a hydrophilic portion of the nonionic surfactant becomes oriented so as to face the slurry composition. The hydrophobic portion of the nonionic surfactant may thus be adsorbed onto the surface of the hydrophobic layer so as to protect the hydrophobic layer from being damaged by the ceria abrasive during a polishing step. Particularly, the nonionic surfactant may form a passivation layer on the hydrophobic layer so as to prevent particles of the ceria abrasive from making direct contact with the hydrophobic layer. Thus, the polishing rate of the hydrophobic layer may be greatly reduced. Additionally, a large proportion of the nonionic surfactant in the slurry composition becomes attached to the hydrophobic layer, and thus the presence of the nonionic surfactant may not substantially lessen the polishing rate of the hydrophilic layer. Therefore, the slurry composition of the present invention including the nonionic surfactant may have a relatively high polishing rate for the hydrophilic layer and at the same time a relatively low polishing rate for the hydrophobic layer.

In accordance with an example embodiment of the present invention, the slurry composition may include the nonionic surfactant in a range of about 0.001 to about 0.1 percent by weight based on a total weight of the slurry composition.

In accordance with another example embodiment of the present invention, the slurry composition may further include a dispersing agent for dispersing the ceria abrasive. The dispersing agent may enhance the polishing efficiency of the ceria abrasive. The dispersing agent may include a polymeric substance such as polyacrylic acid. The polymeric substance included in the dispersing agent may be adsorbed onto the particles of the ceria abrasive to thereby enhance the dispersibility of the ceria abrasive in the slurry composition by using an electrostatic repulsion and a steric hindrance. The enhanced dispersibility of the ceria abrasive when the slurry includes a dispersing agent may prevent components of the slurry composition from becoming agglomerated. Furthermore, the dispersing agent may increase the viscosity of the slurry composition to thereby reduce a noise during the polishing process.

An amount of the dispersing agent added to the slurry may be varied according to the amount of the ceria abrasive in the slurry composition. For example, the slurry composition may include about 0.5 to about 3.5 percent by weight of the dispersing agent based on a total amount of the slurry composition.

In accordance with another example embodiment of the present invention, the slurry composition may further include a pH-controlling agent. The pH-controlling agent may adjust the pH of the slurry composition within a proper range. For example, the pH of the slurry composition may be adjusted in a range of about 5 to about 8.

The slurry composition of the present invention will be more fully described with reference to the following Examples and a Comparative Example.

Preparation of Slurry Compositions

### EXAMPLE 1

A slurry composition according to the present invention was prepared by mixing about 0.5 percent by weight of a ceria abrasive, about 1.0 percent by weight of a dispersing agent, about 0.02 percent by weight of polyoxyethylene lauryl ether as a nonionic surfactant, all weight percents based on the total weight of the slurry composition, with the remainder consisting of water.

### EXAMPLE 2

A slurry composition according to the present invention was prepared by mixing about 0.5 percent by weight of a ceria abrasive, about 1.0 percent by weight of a dispersing agent, about 0.02 percent by weight of polyoxyethylene cetyl ether as a nonionic surfactant, with the remainder consisting of water.

### EXAMPLE 3

A slurry composition according to the present invention was prepared by mixing about 0.5 percent by weight of a ceria abrasive, about 1.0 percent by weight of a dispersing agent, about 0.02 percent by weight of polyoxyethylene oleyl ether as a nonionic surfactant, with the remainder consisting of water.

### EXAMPLE 4

A slurry composition according to the present invention was prepared by mixing about 0.5 percent by weight of a ceria abrasive, about 1.0 percent by weight of a dispersing agent, about 0.02 percent by weight of polyoxyethylene sorbitan monolaurate as a nonionic surfactant, with the remainder consisting of water.

### EXAMPLE 5

A slurry composition according to the present invention was prepared by mixing about 0.5 percent by weight of a ceria abrasive, about 1.0 percent by weight of a dispersing agent, about 0.02 percent by weight of polyoxyethylene isooctylphenyl ether as a nonionic surfactant, with the remainder consisting of water.

### EXAMPLE 6

A slurry composition according to the present invention was prepared by mixing about 0.5 percent by weight of a ceria abrasive, about 1.0 percent by weight of a dispersing agent, about 0.01 percent by weight of polyoxyethylene oleyl ether as a nonionic surfactant, with the remainder consisting of water.

### EXAMPLE 7

A slurry composition according to the present invention was prepared by mixing about 0.5 percent by weight of a ceria abrasive, about 1.0 percent by weight of a dispersing agent, about 0.02 percent by weight of polyoxyethylene oleyl ether as a nonionic surfactant, with the remainder consisting of water.

### EXAMPLE 8

A slurry composition according to the present invention was prepared by mixing about 0.5 percent by weight of a ceria abrasive, about 1.0 percent by weight of a dispersing agent, about 0.05 percent by weight of polyoxyethylene oleyl ether as a nonionic surfactant, with the remainder consisting of water.

### COMPARATIVE EXAMPLE

A comparative slurry composition was prepared by mixing about 0.5 percent by weight of a ceria abrasive, about 1.0 percent by weight of a dispersing agent, with the remainder consisting of water.

Types and amounts of the nonionic surfactant included in the slurry compositions prepared in Examples 1 to 8 as described above are summarized in Table 2 below.

TABLE 2

| | Type of Surfactant | Amount [wt %] |
|---|---|---|
| Example 1 | Polyoxyethylene Lauryl Ether | 0.02 |
| Example 2 | Polyoxyethylene Cetyl Ether | 0.02 |
| Example 3 | Polyoxyethylene Oleyl Ether | 0.02 |
| Example 4 | Polyoxyethylene Sorbitan Monolaurate | 0.02 |
| Example 5 | Polyoxyethylene Isooctylphenyl Ether | 0.02 |
| Example 6 | Polyoxyethylene Oleyl Ether | 0.01 |
| Example 7 | Polyoxyethylene Oleyl Ether | 0.02 |
| Example 8 | Polyoxyethylene Oleyl Ether | 0.05 |

Evaluation of Polishing Selectivities According to Types of Nonionic Surfactant

To evaluate polishing rates and polishing selectivities in accordance with types of the nonionic surfactant used in the slurry compositions, silicon wafer test samples were prepared each comprising a silicon oxide layer as a hydrophilic layer and a polysilicon layer as a hydrophobic layer. A CMP process was performed on each of the test samples using one of the slurry compositions prepared according to Examples 1 to 5. The CMP process was carried out using Reflexion (the trade name of a product manufactured by AMAT). The process conditions of the CMP process are shown in Table 3 below.

TABLE 3
Process Conditions

| | | |
|---|---|---|
| Pressure [psi] | Inner Tube | 4.4 |
| | Retaining Ring | 7 |
| | Membrane | 2 |
| Rotation Speed [rpm] | Head | 78 |
| | Platen | 86 |

| | |
|---|---|
| Flow Rate of Slurry Composition [mL/min] | 200 |
| Pressure of Conditioner [psi] | 5.9 |
| Rotation Speed of Conditioner [rpm] | 100 |

The silicon oxide layer and the polysilicon layer of each silicon wafer test sample were polished using the slurry compositions prepared according to Examples 1 to 5 under the above-mentioned conditions. The polishing rates of the layers and the polishing selectivities between the silicon oxide layer and the polysilicon layer are shown in Table 4 below.

TABLE 4

| | | Polishing Rate of | |
|---|---|---|---|
| | Polishing Rate of Silicon | Polysilicon | Polishing |
| | Oxide Layer [Å/min] | Layer [Å/min] | Selectivity |
| Example 1 | 2,035 | 62 | 33:1 |
| Example 2 | 2,153 | 31 | 70:1 |
| Example 3 | 2,198 | 16 | 134:1 |
| Example 4 | 2,031 | 41 | 50:1 |
| Example 5 | 2,201 | 28 | 78:1 |

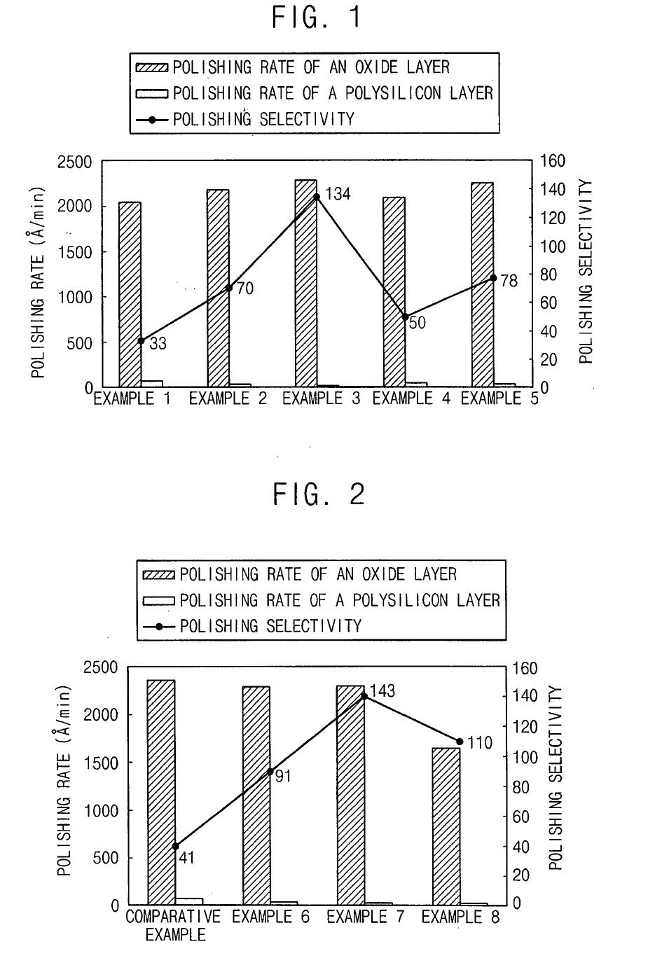

FIG. 1 is a graph illustrating the data of Table 4, that is showing polishing rates and polishing selectivities for a polysilicon layer and a silicon oxide layer on which CMP processes were performed using slurry compositions prepared in accordance with Examples 1 to 5.

As shown in Table 4 and FIG. 1, it can be seen that the slurry compositions prepared in accordance with Examples 1 to 5 had relatively high polishing rates, between about 2,000 Å/min and about 2,200 Å/min, for the silicon oxide layer, while these slurry compositions also had relatively low polishing rates, between about 30 Å/min and about 60 Å/min, for the polysilicon layer. In addition, it was confirmed that the slurry compositions prepared in accordance with Examples 1 to 5 demonstrated high polishing selectivities of at least about 30:1. Particularly, the slurry composition that included polyoxyethylene oleyl ether as the nonionic surfactant according to Example 3 exhibited a particularly high polishing selectivity of about 134:1, which was substantially higher than those of the slurry compositions including the other types of nonionic surfactants. Therefore, it may be noted that a slurry composition in accordance with the present invention may be effectively applied during the CMP process in which the silicon oxide layer may be polished using the polysilicon layer as a polishing stop layer.

Evaluation of Polishing Selectivities According to Amounts of Surfactant

To evaluate polishing rates and polishing selectivities in accordance with the amounts (proportions) of the nonionic surfactant in the slurry compositions, silicon wafer test samples were prepared each comprising a silicon oxide layer as a hydrophilic layer and a polysilicon layer as a hydrophobic layer. A CMP process was performed on each of the test samples using one of the slurry compositions prepared in accordance with Examples 6 to 8 and also using a slurry composition prepared in accordance with the Comparative Example. The CMP process was carried out using Reflexion (manufactured by AMAT) under process conditions substantially the same as those in Table 3. The polishing rates of the layers and the polishing selectivities between the silicon oxide layer and the polysilicon layer are shown in Table 5 below.

TABLE 5

| | | Polishing Rate of | |
|---|---|---|---|
| | Polishing Rate of Silicon | Polysilicon | Polishing |
| | Oxide Layer [Å/min] | Layer [Å/min] | Selectivity |
| Comparative | 2,351 | 57 | 41:1 |
| Example | | | |
| Example 6 | 2,282 | 28 | 91:1 |
| Example 7 | 2,285 | 16 | 143:1 |
| Example 8 | 1,645 | 15 | 110:1 |

FIG. 2 is a graph illustrating the data of Table 5, that is showing polishing rates and polishing selectivities for a polysilicon layer and a silicon oxide layer on which CMP processes were performed using slurry compositions prepared in accordance with Examples 6 to 8 and the Comparative Example.

As shown in Table 5 and FIG. 2, it can be seen that the slurry compositions that included the nonionic surfactant according to Examples 6 to 6 had high polishing selectivities of at least about 90:1 compared with the slurry composition that did not include the nonionic surfactant according to Comparative Example. Particularly, it was confirmed that the slurry composition including about 200 ppm of polyoxyethylene oleyl ether as the nonionic surfactant according to Example 7 exhibited a particularly high polishing selectivity of about 143:1.

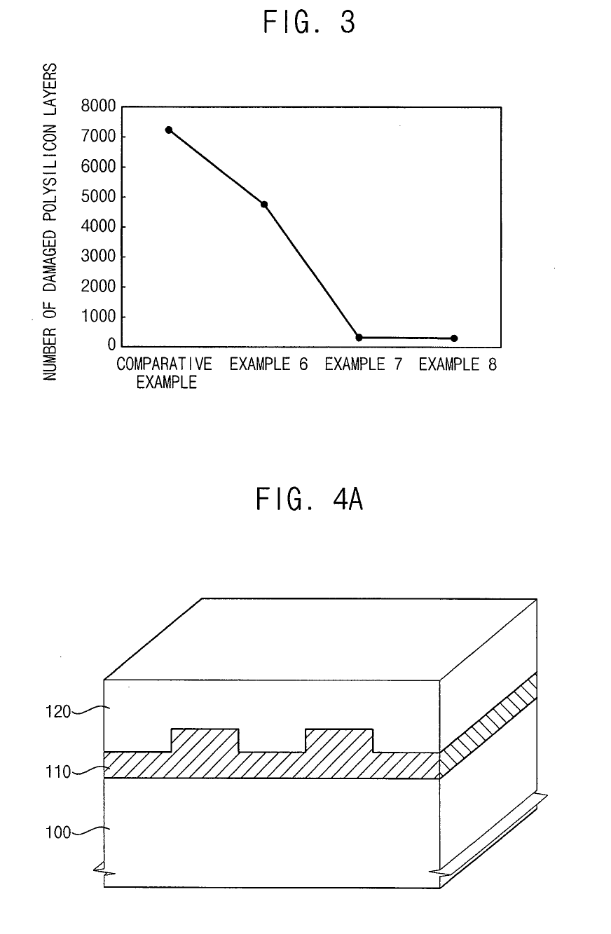

FIG. 3 is a graph showing the number of damaged polysilicon layers resulting from CMP processes that were performed using slurry compositions prepared in accordance with Examples 6 to 8 in contrast with the number of damaged polysilicon layers resulting from a CMP process using the slurry composition of the Comparative example.

It can readily be seen that, as a concentration of polyoxyethylene oleyl ether in the slurry increases, the number of damaged polysilicon layers is reduced. However, once the concentration of polyoxyethylene oleyl ether in the slurry reached a level of about 0.02 percent by weight (Example 7), the number of damaged polysilicon layers was very small, and that low number was not substantially further reduced by a higher concentration of the surfactant (Example 8). Therefore, it may be confirmed that the slurry composition including polyoxyethylene oleyl ether of at least about 0.02 percent by weight may be effectively applied to the polishing process, maximizing the polishing selectivity while minimizing damages to the polysilicon layer.

Method of Polishing an Object Layer

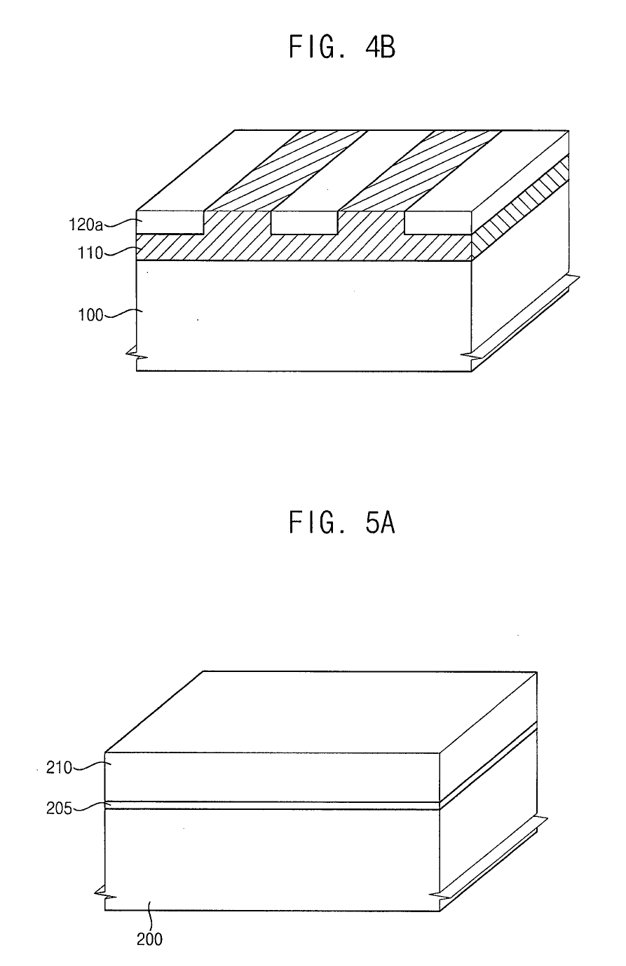

FIGS. 4A to 4B are schematic perspective views illustrating a method of polishing an object layer in accordance with an example embodiment of the present invention.

Referring to FIG. 4A, a first layer 110 is formed on a substrate 100. The first layer 110 may be formed directly on the substrate 100, or may be formed on the substrate by an interposition of a structure such as an electrode, a conductive layer, a conductive layer pattern, an insulation layer or an insulation layer pattern therebetween. The first layer 110 may be formed using a hydrophobic material. For example, the first layer 110 may be formed using polysilicon. In accordance with one example embodiment of the present invention, the first layer 110 may have at least a prominent portion and at least a depressed portion as shown in FIG. 4A. In accordance with another example embodiment of the present invention, the first layer 110 may have an uneven surface, for example a cylindrical shape or a stepped shape. In accordance with still another example embodiment of the present invention, the first layer 110 may have a substantially flat structure. In accordance with still another example embodiment of the present invention, the first layer 110 may include an opening that exposes an underlying structure.

Subsequently, a second layer 120 is formed on the first layer 110. The second layer 120 may be formed using a hydrophilic material. For example, the second layer 120 may be formed using silicon oxide. Examples of types of silicon oxide that may be used in this step include phosphor silicate glass (PSG), borophosphosilicate glass (BPSG), undoped silica glass (USG), spin-on-glass (SOG), tetraethyl orthosilicate (TEOS), plasma-enhanced TEOS (PE-TEOS), high density plasma chemical vapor deposition (HDP-CVD) oxide, etc. In accordance with an example embodiment of the present invention, the second layer 120 may be formed to have a thickness sufficient for completely covering the first layer 110 regardless of the configuration of first layer 110.

Referring to FIG. 4B, the second layer 120 is partially removed by a polishing process, such as a CMP process, until the first layer 110 is exposed. Particularly, a slurry composition in accordance with the present invention including a ceria abrasive, a nonionic surfactant having an HLB value of about 12 to about 17, and water is provided on a polishing pad. The second layer 120 is polished by rubbing the second layer 120 with the polishing pad to partially remove the second layer 120 from the substrate 100. The polishing process may be carried out by rotating the polishing pad and/or the substrate 100 including the first and the second layers 110 and 120, which will be referred to herein as “polishing contact.” During such a polishing process, the substrate 100 may make polishing contact with the polishing pad under a pressurized condition. The second layer 120 may be chemically polished by the slurry composition, and the second layer 120 may at the same time be mechanically polished by the rotation and the pressurization. The polishing pad and the substrate 100 may be rotated in the same directions or in opposite directions. The slurry composition is selected from one of those previously described, so any further explanations in this regard will be omitted herein for brevity.

The slurry composition may have a relatively high polishing rate for the second layer 120 that exhibits the property of hydrophilicity, and also a relatively low polishing rate for the first layer 110 that exhibits the property of hydrophobicity. For example, the slurry composition may have a polishing rate for the second layer 120 in a range of about 1,500 to about 4,000 Å/min, and preferably in a range of about 2,000 to about 4,000 Å/min. The slurry composition may also have a polishing rate for the first layer 110 in a range of about 10 to about 60 Å/min, and preferably in a range of about 10 to about 30 Å/min. Additionally, the slurry composition may have a polishing selectivity of at least about 30:1 between the second layer 120 relative to the first layer 110, and preferably a polishing selectivity of about at least about 100:1.

When a slurry composition according to the present invention is applied to polish a structure that comprises the first layer 110 (having hydrophobicity) and the second layer 120 (having hydrophilicity) formed on the first layer 110 in an example embodiment of the present invention, the second layer 120 may be effectively polished using the first layer 110 as a polishing stop layer.

The polishing process may be performed until an upper face of the first layer 110 is exposed as seen in FIG. 4B. As a result of such polishing of the second layer 120, a second layer pattern 120a is formed on the first layer 110. The second layer pattern 120a may be removed from the substrate 100 through subsequent processes such as a dry etching process or a wet etching process, etc.

In an example embodiment of the present invention, at least one portion of the exposed first layer 110 may be etched. After polishing the second layer 120 until the first layer 110 is exposed, the polishing may be continued such that the exposed first layer 110 may also be polished using the above-mentioned slurry composition by an in-situ polishing process. Accordingly, the first layer 110 may be polished to have a uniform thickness and an even surface. The nonionic surfactant included in the slurry composition may form a passivation layer on the first layer 110, to thereby prevent the first layer 110 from making contact with the ceria abrasive in the slurry composition. As a result, the slurry composition may have a low polishing rate for the first layer 110 resulting in a first layer 110 having a substantially uniform thickness and an even surface.

In example embodiments of the present invention, the above-mentioned polishing process may be advantageously applied to manufacture various structures of a semiconductor device such as an isolation layer, a gate structure, a wiring structure, a pad structure, a contact, a capacitor, and the like.

Method of Manufacturing a Non-Volatile Memory Device

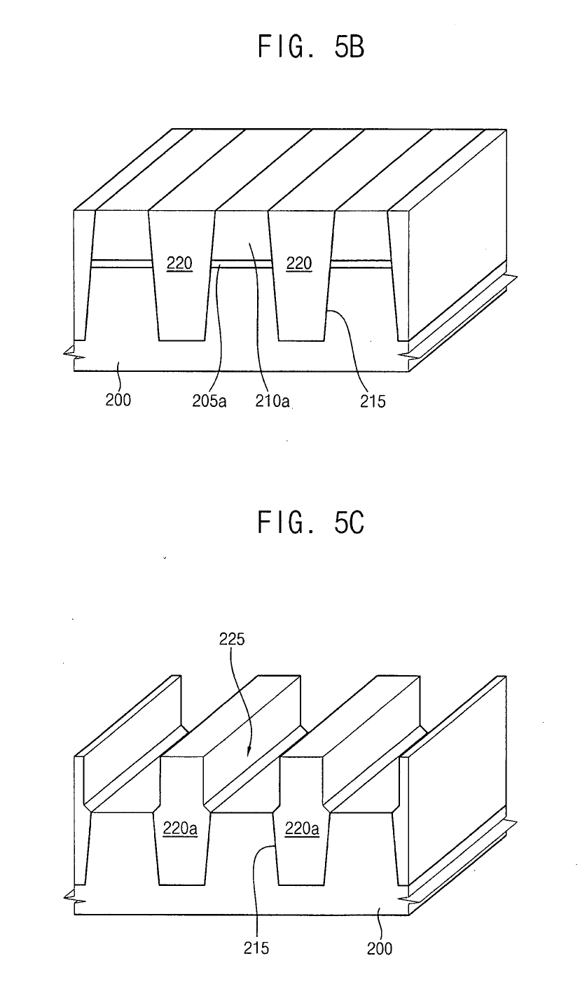

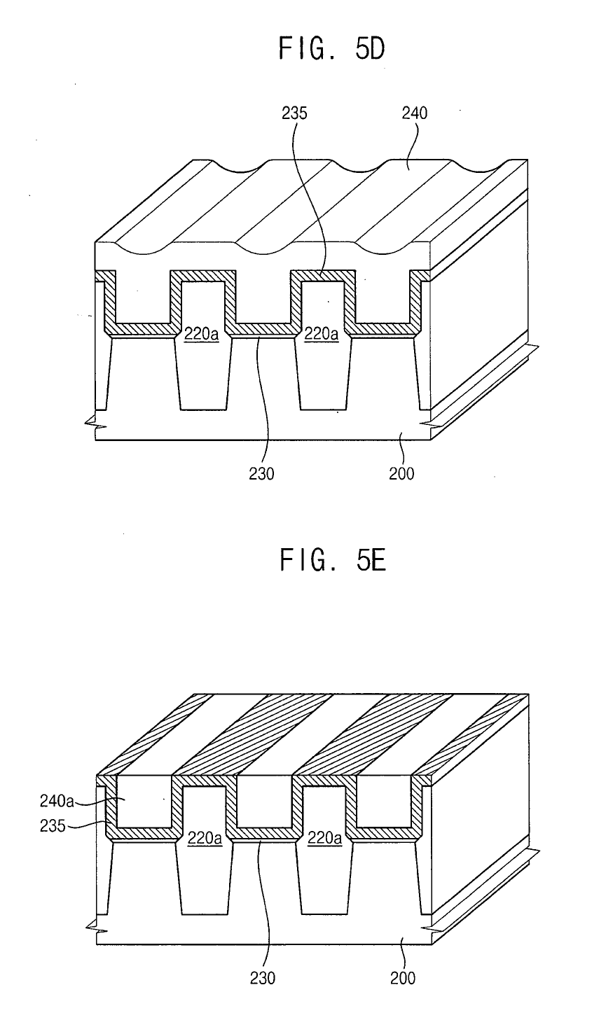

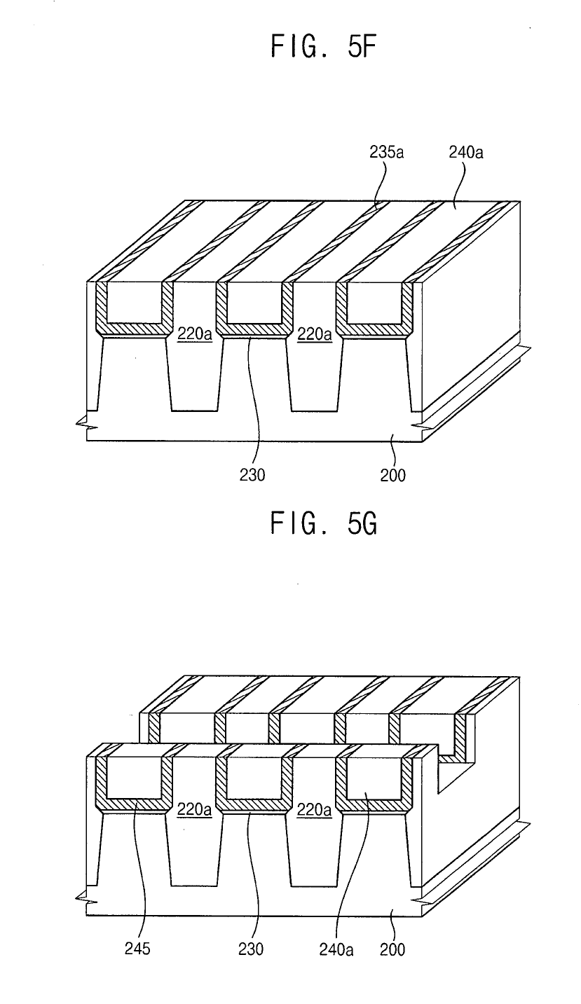

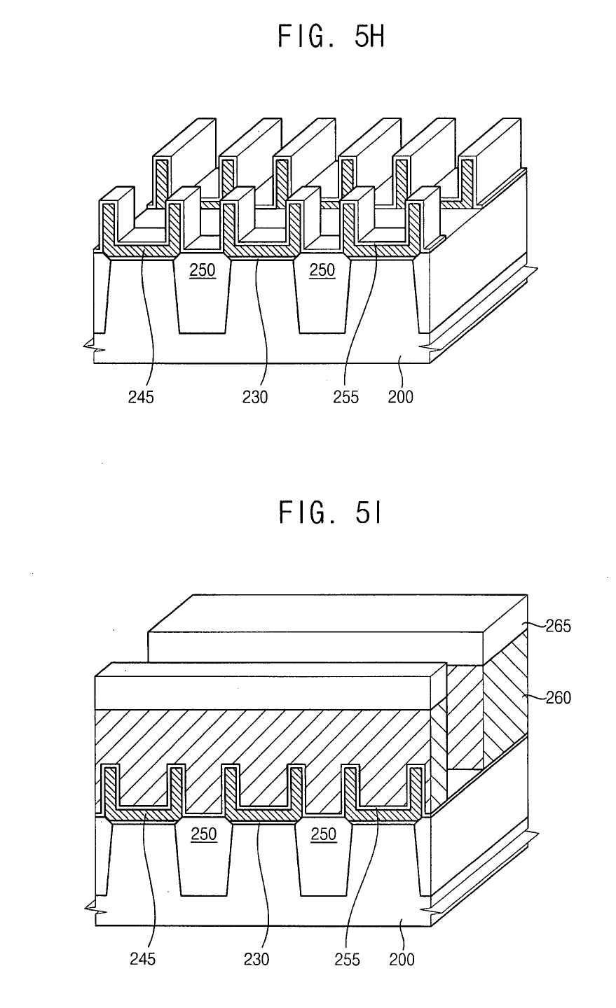

FIGS. 5A to 5I are schematic perspective views illustrating a method of manufacturing a non-volatile memory device in accordance with an example embodiment of the present invention.

Referring to FIG. 5A, a pad oxide layer 205 is formed on a substrate 200. Examples of the substrate 200 may include a silicon wafer, a germanium substrate, a silicon germanium substrate or a silicon-on-insulator (SOI) substrate. The pad oxide layer 205 may be formed, for example, by performing an oxidation process, such as a thermal oxidation process on the substrate 200, or may be formed by depositing silicon oxide through a chemical vapor deposition (CVD) process. The pad oxide layer 205 may be provided for preventing a subsequently formed mask layer 210 from making direct contact with the substrate 200.

The mask layer 210 is formed on the pad oxide layer 205. In one embodiment, the mask layer 210 may be formed using silicon nitride. The mask layer 210 may be provided as a mask pattern that may be used in forming an isolation trench through subsequent processes. The mask layer 210 may also be formed to have a thickness sufficient for forming a floating gate electrode of a non-volatile memory device, wherein the thickness of the floating gate electrode may be mainly determined by the thickness of the mask layer 210. The mask layer 210 may also later be at least partially removed by a cleaning process or a polishing process that are subsequently performed, and thus the mask layer 210 may be formed to have a thickness substantially thicker than a predetermined thickness of the floating gate electrode.

Referring to FIG. 5B, a first photoresist pattern (not shown) may be formed on the mask layer 210 as shown in FIG. 5A. The first photoresist pattern may be formed to selectively expose a region in which an isolation layer will be formed. The mask layer 210 and the pad oxide layer 205 may be anisotropically etched using the first photoresist pattern as an etching mask to thereby form a pad oxide layer pattern 205a and a mask pattern 210a as shown in FIG. 5B.

The substrate 200 may be partially etched using the mask pattern 210a as an etching mask to form a trench 215 at an upper portion of the substrate 200. The trench 215 may define regions in which the floating gate electrode and an isolation layer will be formed. As a result, regions for forming the floating gate electrode and the isolation layer may be simultaneously formed.

A first preliminary isolation layer 220 is formed on the mask pattern 210a to fill the trench 215. The first preliminary isolation layer 220 may be formed using a silicon oxide material. For example, the first preliminary isolation layer 220 may be formed using a silicon oxide material such as BPSG, PSG, BSG, USG, SOG, TEOS, PE-TEOS, HDP-CVD oxide, etc. In accordance with an example embodiment of the present invention, the first preliminary isolation layer 220 may be formed using an oxide that has good gap-filling characteristics by a CVD process to effectively fill the trench 215. For example, the first preliminary isolation layer 220 may be formed using HDP-CVD oxide.

The first preliminary isolation layer 220 may be partially removed to expose the mask pattern 210a. Following this step, the first preliminary isolation layer 220 may divide the substrate 200 into an active region and a field region.

In accordance with an example embodiment of the present invention, a liner film may be formed on an inner wall of the trench 215 before forming the first preliminary isolation layer 220. The liner film may be formed to cure damages to the substrate 200 that may be generated during the etching process for forming the trench 215, and to prevent leakage current from being generated around the trench 215.

Referring next to FIG. 5C, the exposed mask pattern 210a as shown in FIG. 5B is removed from the substrate 200. In accordance with an example embodiment of the present invention, the mask pattern 210a may be removed using an etching substance that has a polishing selectivity relative to the first preliminary isolation layer 220. For example, when the mask pattern 210a includes silicon nitride and the first preliminary isolation layer 220 includes silicon oxide, the mask pattern 210a may be removed by a wet etching process using an etching solution including phosphoric acid.

The pad oxide layer pattern 205a (FIG. 5B) is removed from the substrate 200. In accordance with an example embodiment of the present invention, the pad oxide layer pattern 205a may be removed by a wet etching process to thereby form an opening 225 that may define a region for forming a floating gate. The pad oxide layer pattern 205a may be removed, for example, using a cleaning solution such as an SC-1 solution including ammonium hydroxide, hydrogen peroxide and water, or an SC-2 solution including hydrogen chloride, hydrogen peroxide and water, as known in the art.

While the pad oxide layer pattern 205a is being removed by the wet etching process, sidewalls of an upper portion of the first preliminary isolation layer 220 may be partially etched to form a second preliminary isolation layer 220a including an upper portion that may have a width substantially narrower than a width of the upper portion of the first preliminary isolation layer 220. Therefore, the opening 225 (FIG. 5C) formed between the second preliminary isolation layers 220a may have a width substantially wider than a width of the pad oxide layer pattern 205a (FIG. 5B). Accordingly, the floating gate electrode that will be formed on the active region exposed by the opening 225 may have an extended dimension, to thereby improve a coupling ratio of a gate structure. The second preliminary isolation layer 220a may include an upper portion that protrudes from the substrate 200 and a lower portion filling the trench 215, as shown in FIG. 5C.

The substrate 200 positioned between the second preliminary isolation layers 220a may be exposed by removing the pad oxide layer pattern 205a from the substrate 200.

Referring now to FIG. 5D, a tunnel oxide layer 230 is formed on the portions of substrate 200 exposed between the second preliminary isolation layers 220a. The tunnel oxide layer 230 may be formed using silicon oxide. The tunnel oxide layer 230 may be formed by a thermal oxidation process or a CVD process.

A first conductive layer 235 is then formed on the tunnel oxide layer 230, and also on the sidewalls and an upper face of second preliminary isolation layer 220a. The first conductive layer 235 may be formed so as to only partially fill the opening 225 as shown in FIG. 5D. For example, the first conductive layer 235 may be formed to have a thickness substantially thinner than half of a width of the opening 225 between the second preliminary isolation layers 220a. The first conductive layer 235 may be provided as the floating gate electrode through subsequent process steps. In accordance with an example embodiment of the present invention, the first conductive layer 235 may be formed by depositing polysilicon doped with impurities through a low pressure chemical vapor deposition (LPCVD) process. The step of doping impurities into the polysilicon layer may be carried out, for example, by a POCl₃ diffusion process, an ion implantation process or an in-situ doping process.

In accordance with an example embodiment of the present invention, a wet etching process may be performed on the first conductive layer 235 to enlarge a surface of the first conductive layer 235. For example, the wet etching process may be carried out using an etching solution such as a hydrofluoric acid solution.

A sacrificial layer 240 is then formed on the first conductive layer 235 to completely fill the remaining portion of opening 225. The sacrificial layer 240 may be formed by depositing a silicon oxide material such as BPSG, PSG, BSG, USG, SOG, TEOS, PE-TEOS, HDP-CVD oxide, etc. In accordance with an example embodiment of the present invention, the sacrificial layer 240 may be formed using USG.

Referring next to FIG. 5E, the sacrificial layer 240 is partially removed by a polishing process, such as a CMP process, until the first conductive layer 235 is exposed. An upper portion of the sacrificial layer 240 positioned over the first conductive layer 235 may be removed using the first conductive layer 235 as a polishing stop layer.

When the first conductive layer 235 includes polysilicon and the sacrificial layer 240 includes silicon oxide, the polishing process is preferably performed using a slurry composition according to the present invention that may have a relatively high polishing rate for the sacrificial layer 240 and a correspondingly low polishing rate for the first conductive layer 235. The polysilicon of the first conductive layer 235 may exhibit the property of hydrophobicity, and the silicon oxide of the sacrificial layer 240 may exhibit the property of hydrophilicity. Thus, in accordance with the present invention, the polishing process may be carried out using a slurry composition that may have a high polishing selectivity between the hydrophilic layer and the hydrophobic layer.

Particularly, the preferred slurry composition in accordance with the present invention includes a ceria abrasive, a nonionic surfactant having an HLB value of about 12 to about 17, and water. The slurry composition has previously been described so any further explanations in this regard will be omitted herein for brevity.

The slurry composition may have a high polishing rate for the sacrificial layer 240 having a hydrophilic property, and also a very low polishing rate for the first conductive layer 235 having a hydrophobic property. For example, the slurry composition may have the polishing rate for the sacrificial layer 240 in a range of about 1,500 to about 4,000 Å/min, and preferably in a range of about 2,000 to about 4,000 Å/min. The slurry composition may have the polishing rate for the first conductive layer 235 in a range of about 10 to about 60 Å/min, and preferably in a range of about 10 to about 30 Å/min. Additionally, the slurry composition may have at least a polishing selectivity of about 30:1 between the sacrificial layer 240 and the first conductive layer 235, and preferably a polishing selectivity of at least about 100:1. Thus, the sacrificial layer 240 may be effectively polished using the first conductive layer 235 as a polishing stop layer.

Referring next to FIG. 5F, an exposed portion of the first conductive layer 235 (FIG. 5E) is partially removed until the second preliminary isolation layer 220a is exposed.

In accordance with an example embodiment of the present invention, the first conductive layer 235 may be partially removed by continuing the polishing process using the slurry composition in accordance with the present invention that may be applied to remove the sacrificial layer 240, as previously described. While the exposed first conductive layer 235 is being polished using the slurry composition, the nonionic surfactant included in the slurry composition may form a passivation layer on the first conductive layer 235 to thereby prevent the first conductive layer 235 from making contact with the ceria abrasive in the slurry composition. As a result, the first conductive layer 235 may be polished so as to have a substantially uniform thickness and an even surface resulting in a first conductive layer 235 having a good profile.

Thus the upper portion of the first conductive layer 235 may be removed to expose the second preliminary isolation layer 220a and to form a preliminary floating gate electrode 235a that may be isolated in a unit cell of a memory device.

Referring next to FIG. 5G, a second photoresist pattern (not shown) may be formed on the sacrificial layer pattern 240a and the preliminary floating gate electrode 235a. The second photoresist pattern may be formed so as to cover a region in which the completed floating gate electrode will be formed.

The preliminary floating gate electrode 235a may be partially etched using the second photoresist pattern as an etching mask to form a floating gate electrode 245 having an isolated U shape. The preliminary floating gate electrode 235a may have such a U-shaped configuration extending without interruption along a first direction that is substantially parallel to a lengthwise direction of the active region of the substrate 200 (as seen in FIG. 5F), but the completed floating gate electrode 245 has a U-shape that may be isolated along the first direction so as to have an exposed frontal side and an exposed rear side along the first direction (as seen in FIG. 5G).

The second photoresist pattern may be removed from the substrate 200 by performing an ashing process and/or a stripping process, as known in the art.

Referring next to FIG. 5H, the sacrificial layer pattern 240a that remains inside the floating gate electrode 245 is removed from the substrate 200. The upper portion of the second preliminary isolation layer 220a (FIG. 5G) adjacent to the sidewall of the floating gate electrode 245 may also be removed from the substrate 200. As a result of this process step, an isolation layer 250 may remain in the trench but having a height that is substantially lower than the earlier height of the second preliminary isolation layer 220a.

In the formation of the isolation layer 250, the upper portion of the second preliminary isolation layer 220a protruding from the substrate 200 may be at least partially removed. As a result of the steps of removing both the sacrificial layer pattern 240a and the upper portion of the second preliminary isolation layer 220a, an upper face, lateral sides, a frontal side and a rear side of the floating gate electrode 245 may be exposed.

A dielectric layer 255 is then formed on the upper face and lateral sides of the floating gate electrode 245 and also on the isolation layer 250, as shown in FIG. 5H. The dielectric layer 255 may be sequentially formed to have a multi-layered structure. including a silicon oxide layer, a silicon nitride layer and a silicon oxide layer. In accordance with an example embodiment of the present invention, the dielectric layer 255 may be formed using a high dielectric material such as a metal oxide having a dielectric constant substantially higher than that of silicon oxide.

As described above, the floating gate electrode 245 may be formed so as to have an isolated U-shape pattern to include exposed portions such an upper face, lateral sides, a frontal side and a rear side, and thus the floating gate electrode 245 may have a large surface area. Therefore, the dielectric layer 255 formed on the floating gate electrode 245 may also have a very large surface area, and the coupling ratio of a unit cell in a non-volatile memory device incorporating such a floating gate electrode may be significantly enhanced.

Referring next to FIG. 5I, a second conductive layer 260 is formed on the dielectric layer 255. In accordance with an example embodiment of the present invention, the second conductive layer, preferably having a multi-layered structure, may be formed by first depositing polysilicon doped with impurities and thereafter by depositing metal suicide on the doped polysilicon. A hard mask layer may then be formed on the second conductive layer 260.

A photolithography process may then be performed on the hard mask layer and the second conductive layer to form a hard mask pattern 265 and a control gate electrode 260 on the substrate 200. As a result, a completed gate structure of the non-volatile memory device is formed that includes the tunnel oxide layer 230, the floating gate electrode 245, the dielectric layer 255, the control gate electrode 260 and the hard mask pattern 265.

According to the present invention, the slurry compositions as described may have a relatively high polishing rate for a hydrophilic layer, such as a silicon oxide layer, and, at the same time, a relatively low polishing rate for a hydrophobic layer, such as a polysilicon layer. Therefore, such a slurry composition may be effectively applied during a polishing process in which the hydrophobic layer is used as a polishing stop layer and the hydrophilic layer is used as a polishing object layer. Additionally, after the hydrophilic layer is polished using the hydrophobic layer as the polishing stop layer, the hydrophobic layer may also be effectively polished using the same slurry composition so as to have a substantially uniform thickness and an even surface. Furthermore, the slurry compositions of this invention may effectively prevent the surface of the hydrophobic layer from being damaged by the abrasive included in the slurry composition.

The foregoing description is illustrative of the present invention and is not to be construed as limiting thereof. Although a few example embodiments of the present invention have been described, those skilled in the art will readily appreciate that many modifications are possible in those example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A slurry composition comprising:
a ceria abrasive;
a nonionic surfactant having a hydrophilic-lipophilic balance (HLB) value in a range of about 12 to about 17; and
water.

2. The slurry composition of claim 1, wherein the nonionic surfactant is selected from the group consisting of polyoxyethylene lauryl ether, polyoxyethylene cetyl ether, polyoxyethylene oleyl ether, polyoxyethylene sorbitan monolaurate, polyoxyethylene isooctylphenyl ether and mixtures thereof.

3. The slurry composition of claim 1, wherein the slurry composition consists essentially of:
about 0.001 to about 5 percent by weight based on the total weight of the slurry composition of the ceria abrasive;
about 0.001 to about 0.1 percent by weight of the nonionic surfactant; and
the balance being water.

4. The slurry composition of claim 1, further comprising a dispersing agent effective for dispersing the ceria abrasive.

5. The slurry composition of claim 4, wherein the dispersing agent comprises polyacrylic acid.

6. The slurry composition of claim 4, wherein the slurry composition consists essentially of:
about 0.001 to about 5 percent by weight based on the total weight of the slurry composition of the ceria abrasive;
about 0.5 to about 3.5 percent by weight of the dispersing agent;
about 0.001 to about 0.1 percent by weight of the nonionic surfactant; and
the balance being water.

7. The slurry composition of claim 1, wherein the ceria abrasive has an average particle size in a range of about 50 to about 400 nm.

8. The slurry composition of claim 1, wherein the ceria abrasive has an average particle size in a range of about 100 to about 200 nm.

9. The slurry composition of claim 1, wherein the slurry composition has a pH of about 5 to about 8.

10. A method of polishing an object layer comprising:
forming a polishing stop layer on a substrate;
forming the object layer on the polishing stop layer; and
polishing the object layer by bringing the object layer into contact with a polishing pad while a slurry composition is provided to the polishing pad until at least a portion of the polishing stop layer is exposed, wherein the slurry composition includes a ceria abrasive, a nonionic surfactant having a hydrophilic-lipophilic balance (HLB) value in a range of about 12 to about 17, and water.

11. The method of claim 10, wherein the polishing stop layer exhibits the property of hydrophobicity and the object layer exhibits the property of hydrophilicity.

12. The method of claim 10, wherein the polishing stop layer comprises polysilicon having the property of hydrophobicity, and the object layer comprises silicon oxide having the property of hydrophilicity.

13. The method of claim 11, wherein a polishing selectivity of the slurry composition between the object layer and the polishing stop layer is in a range of about 30:1 to about 150:1.

14. The method of claim 10, wherein the nonionic surfactant comprises at least one member selected from the group consisting of polyoxyethylene lauryl ether, polyoxyethylene cetyl ether, polyoxyethylene oleyl ether, polyoxyethylene sorbitan monolaurate and polyoxyethylene isooctylphenyl ether.

15. The method of claim 10, wherein the slurry composition consists essentially of:
about 0.001 to about 5 percent by weight of the ceria abrasive;
about 0.001 to about 0.1 percent by weight of the nonionic surfactant; and
the balance being water.

16. The method of claim 10, wherein the slurry composition further comprises a dispersing agent effective for dispersing the ceria abrasive.

17. A method of manufacturing a non-volatile memory device comprising the steps of:
forming isolation layers having upper portions protruding from a substrate;
forming a tunnel oxide layer on the substrate between the isolation layers;
forming a conductive layer on the tunnel oxide layer and on sidewalls and upper faces of the isolation layers;
forming a sacrificial layer on the substrate to cover the conductive layer;
polishing the sacrificial layer by a polishing process using a slurry composition until at least a portion of the conductive layer is exposed, wherein the slurry composition includes a ceria abrasive, a nonionic surfactant having a hydrophilic-lipophilic balance (HLB) value in a range of about 12 to about 17, and water;
at least partially removing the exposed conductive layer until the upper faces of the isolation layers are exposed to form a floating gate electrode on the substrate;
removing the sacrificial layer and the upper portions of the isolation layers protruding from the substrate to expose the floating gate electrode;
forming a dielectric layer on the floating gate electrode; and
forming a control gate electrode on the dielectric layer.

18. The method of claim 17, wherein the conductive layer is formed using polysilicon, and the sacrificial layer is formed using silicon oxide.

19. The method of claim 17, wherein in the step of polishing the sacrificial layer, a polishing selectivity of the slurry composition between the sacrificial layer and the conductive layer is in a range of about 30:1 to about 150:1.

20. The method of claim 17, wherein the nonionic surfactant is at least one member selected from the group consisting of polyoxyethylene lauryl ether, polyoxyethylene cetyl ether, polyoxyethylene oleyl ether, polyoxyethylene sorbitan monolaurate and polyoxyethylene isooctylphenyl ether.

21. The method of claim 17, wherein the step of at least partially removing the exposed conductive layer is carried out by continuing the polishing process with the same slurry composition used for polishing the sacrificial layer.

22. The method of claim 21, wherein the conductive layer is removed at a polishing rate of about 10 to about 60 Å/min.

23. The method of claim 17, wherein the conductive layer is formed to have a thickness substantially thinner than half of a width between the isolation layers.
